(19) United States
(12) Patent Application Publication
(10) Pub. No.: US 2008/0017981 A1
(43) Pub. Date: Jan. 24, 2008

(54) Compliant Bumps for Integrated Circuits Using Carbon Nanotubes

(75) Inventor: Zvi Yaniv, Austin, TX (US)

Correspondence Address: FISH & RICHARDSON P.C., P.O BOX 1022, Minneapolis, MN, 55440-1022, US

(73) Assignee: NANO-PROPRIETARY, INC., Austin, TX (US)

(21) Appl. No.: 11/750,225

(22) Filed: May 17, 2007

Related U.S. Application Data
(60) Provisional application No. 60/808,800, filed on May 26, 2006.

(51) Int. Cl. H01L 23/48

(52) U.S. Cl. 257/737

(57) ABSTRACT

Complaint bumps used for interconnections between integrated circuit chips are made with carbon nanotubes.

This application for patent claims priority to U.S. Provisional Patent Application Ser. No. 60/808,800, which is hereby incorporated by reference herein.

### BACKGROUND INFORMATION

High-frequency, high-power (e.g., amplifiers) present a host of problems for circuit designers. For example, amplifier integrated circuits were traditionally mounted to other integrated circuit using a “face up” methodolody. In other words, the amplifier integrated circuit was coupled, face up, to the other integrated circuit. The amplifier communicated with the other integrated circuit via connecting wires. This orientation allowed heat generated from the amplifier to dissipate. However, as high-power amplifiers began to function at increasingly higher frequencies, the use of such connecting wired proved problematic. For instance, the connecting wires generated high inductances that lowered the amplification capabilities of the amplifier. To counter the high inductances, the amplifiers were coupled to other integrated circuits using “flip-chip” technology. In a flip-chip orientation, the amplifier is coupled to another integrated circuit face down, not face up. Instead of communicating with the second integrated circuit via connecting wires, the amplifier communicates using bumps or ball-like projections from the other integrated circuit. While this orientation addressed the inductance issue, heat was less easily dissipated. Poor thermal conductivity, in turn, degrades circuit performance (e.g., amplification). Thus, as high power, high frequency integrated circuits become more prevalent, there is a vital need to connect these circuits to other circuits using methodologies that generate low inductance while still allowing for adequate heat dissipation.

To that end, U.S. Pat. No. 5,508,228 provides a flip-chip orientation wherein the connecting bumps are compliant. In other words, the bumps comprise a polymer-based core with a metallic covering. Thus, when an integrated circuit is coupled to, for example, another integrated circuit, the ductile bump provides electrically conductive cushioning between the two circuits. If the thermal and electrical conductivity of the compliant bumps can be improved, however, greater improvements in circuit performance (e.g., amplification) are possible.

### BRIEF DESCRIPTION OF THE DRAWINGS

FIGS. 1A-1M illustrate a proceed for manufacturing an integrated circuit with complaint bumps in accordance with embodiments of the present invention;

FIG. 2 illustrates a flip-flop configured in accordance with embodiments of the present invention.

### DETAILED DESCRIPTION

U.S. Pat. No. 5,508,228, hereby incorporated by reference, describes electrically connective complaint bumps for an adhesive flip chip integrated circuit device and methods for making the same. The compliant bumps are advantageous over traditional flip chip connectors, such as solid metal bumps, that can lose electrical contact between two integrated circuits for a variety of reasons, such as gross delamination and tensile stress cracking. Furthermore, solid metal bumps suffer from adhesive creep-relaxation. In addition, the coefficient of thermal expansion of a solid metal bump is typically much lower than that of the adhesive that holds the flip chip device in contact with the substrate. As the flip chip increases in temperature, therefore, the adhesive expands faster than does the bump. This causes the flip chip to separate from the substrate. This thermal expansion, consequently, opens the circuit between the flip chip and substrate and electrical conductivity is sacrificed.

Compliant bumps solve many of the shortcomings associated with solid bump technologies. Compliant bumps, with a polymer core, allow bumps that can adjust for warp of nonplanarities in substrate and for wire bond pad height non-uniformities.

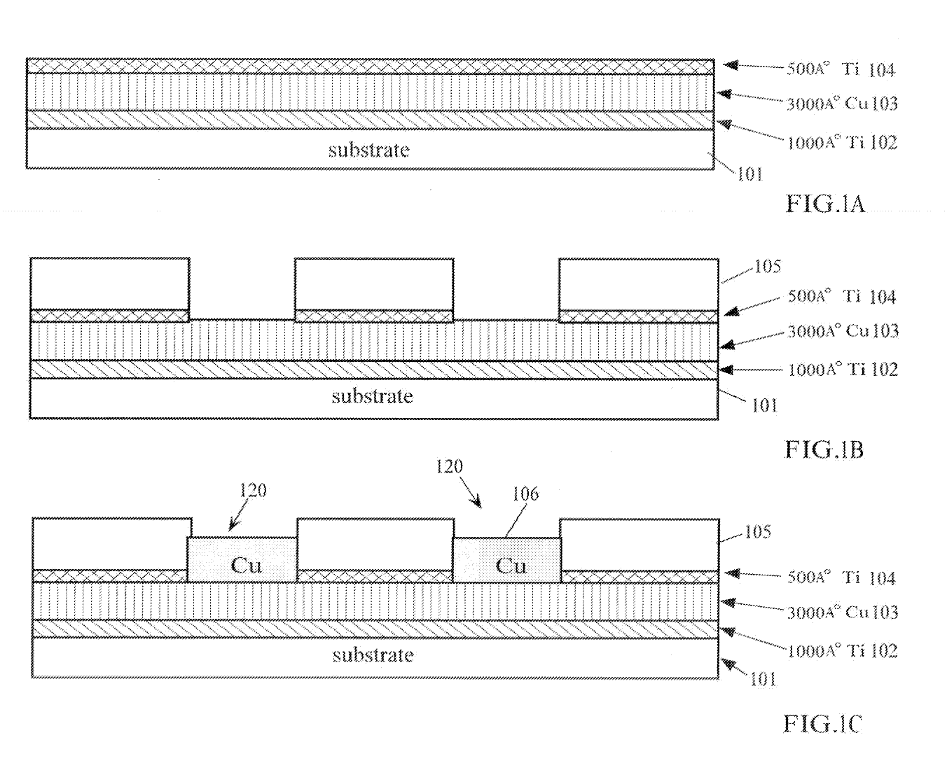

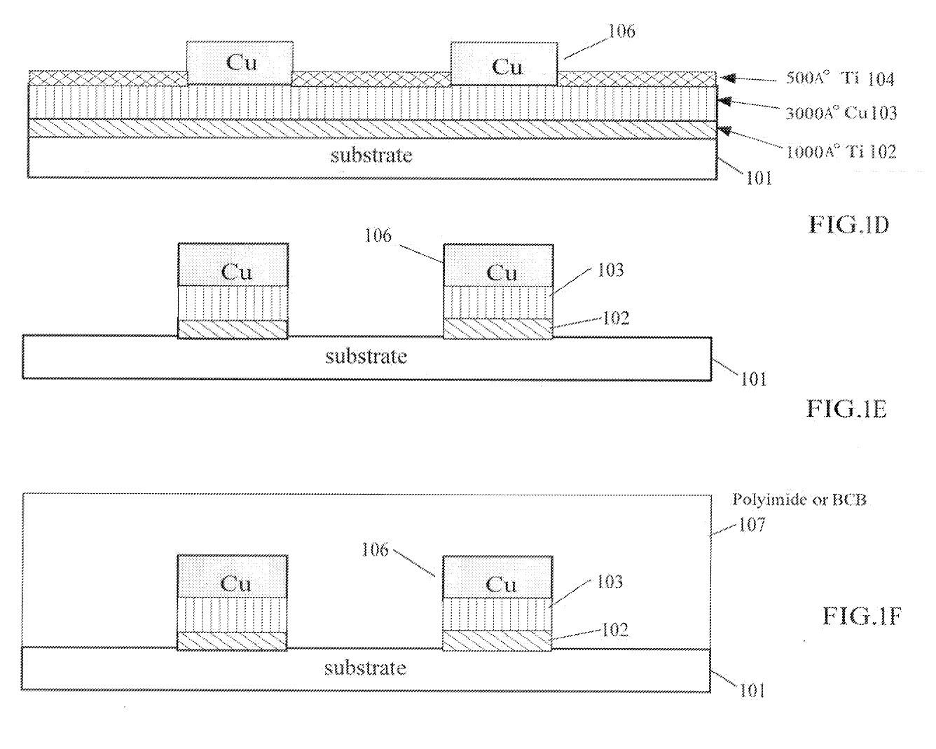

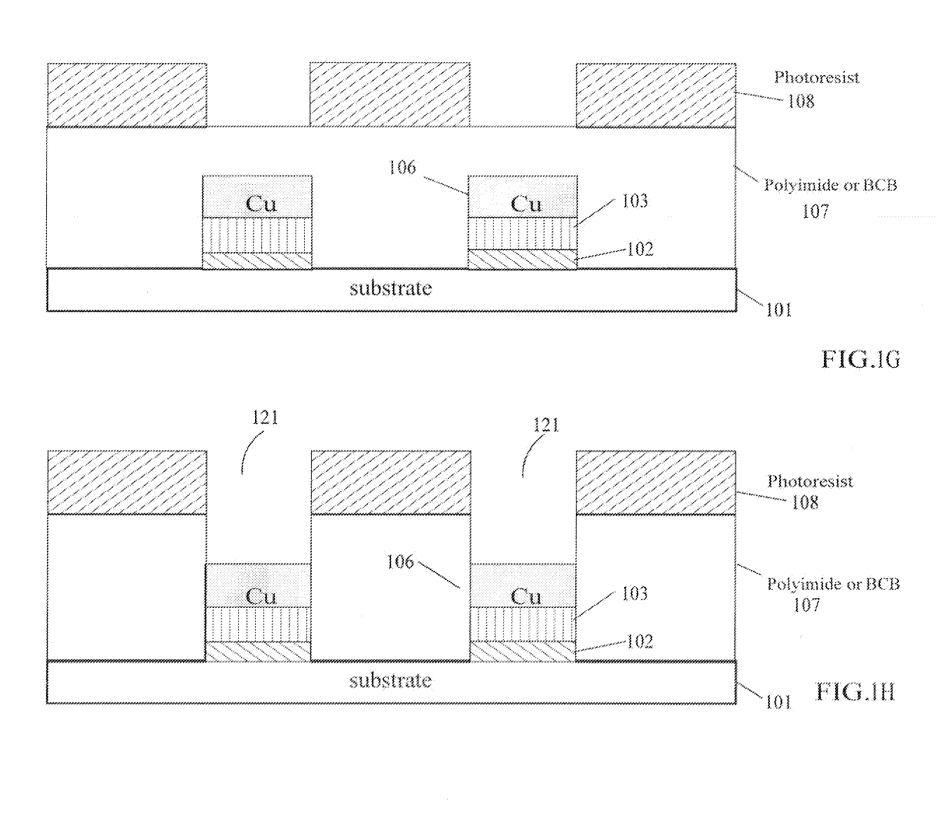

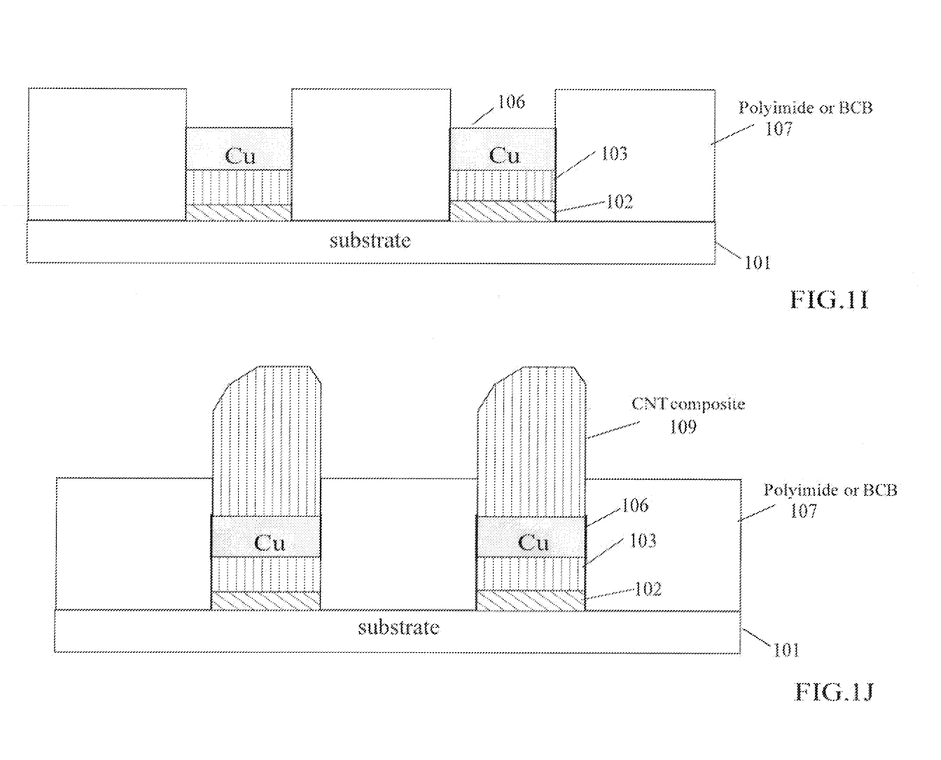

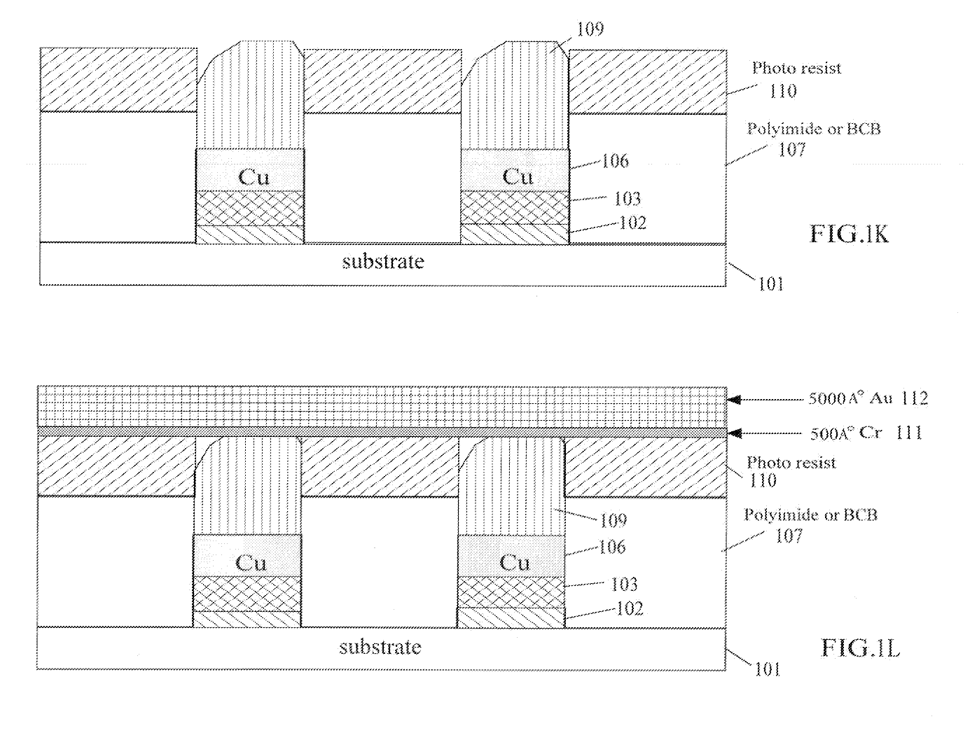

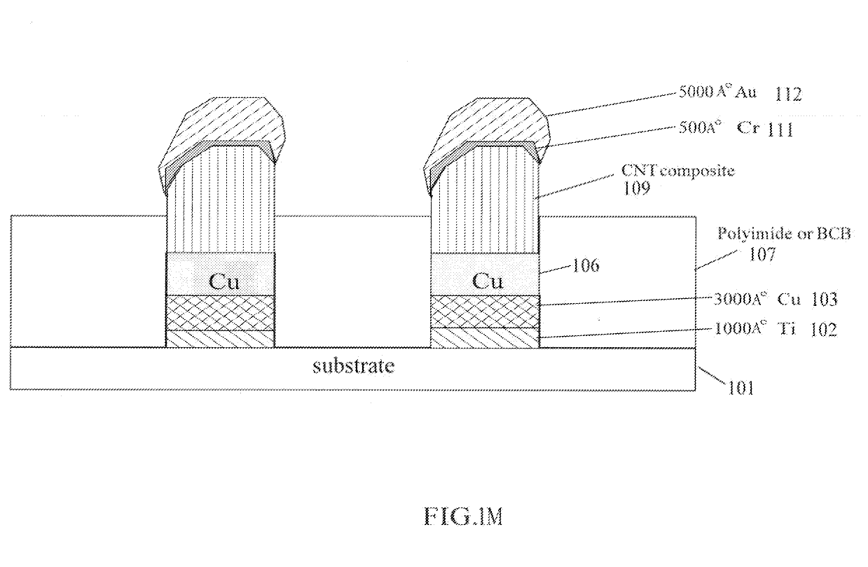

As partially described in U.S. Pat. No. 5,508,228, in one embodiment of the present invention, it is possible to form a compliant bump on a fabricated semiconductor wafer. FIGS. 1A-1M illustrate a process of forming a compliant bump on a pre-existing semiconductor device. Thee process flow that FIGS. 1A-1M illustrate provides an improved method for forming a complaint bump on an already fabricated integrated circuit flip chip assembly.

FIG. 1A illustrates a substrate 101, such as a silicon substrate onto which are deposited layers of titanium 102 (e.g., 1000 Å), copper 103 (e.g., 3000 Å), and titanium 104 (500 Å). In FIG. 1B, the titanium conductive lines 104 are patterned and etched with photoresist 105. In FIG. 1C, the gaps 120 are plated with copper 106. In FIG. 1D, a strip resist process is performed on the photoresist 105. In FIG. 1E, the interconnect metals 102-104 are etched. In FIG. 1F, the entire substrate 101 is then coated and curved with polyimide or a BCB (BCB=bisbenzocyclontene) material a 107. In FIG. 1G, photoresist 108 is used to pattern via holes. In FIG. 1H, a reactive ion etch is performed on the polyimide or BCB material 107 to create via holes 121.

In FIG. 1I, a strip resist process is performed again. In FIG. 1J, a CNT (carbon nanotube) composite material 109 is deposited and cured. The CNT composite material 109 may be a mixture of carbon nanotubes and polyimide of BCB material. Alternatively, CNTs may be grown or deposited on the copper 106. The CNT composite material deposition is not limited by printing or dispensing methods, but it can also be patterned with wet or dry etching with a lithography method. In FIG. 1K, a photoresist 110 is applied. In FIG. 1L, chromium 111 (e.g., 500 Å) and gold 112 (e.g., 5000 Å) layers are deposited, and in FIG. 1M, these layers 111-112 are etched leaving the compliant bumps as illustrated.

The carbon nanotubes in the compliant bump may be aligned or unaligned. In addition, the carbon nanotubes may be single walled or multi-walled. The use of carbon nanotubes in the core of the compliant bumps improves the thermal and electric conductivity of the bumps themselves due to the heightened conductivity inherent to carbon nanotubes. This improvement in thermal conductivity remedies much of the thermal dissipation problems traditionally associated with flip chip orientations. The carbon nanotubes, in one embodiment of the invention, are 15 μm in length and have a thermal conductivity of 1400 W/m-K. The use of the invention with high power, high frequency circuits (e.g., amplifiers) is one example of utility for the carbon nanotube compliant bumps. In another embodiment of the invention, carbon nanotubes are employed in the coating of the bump.

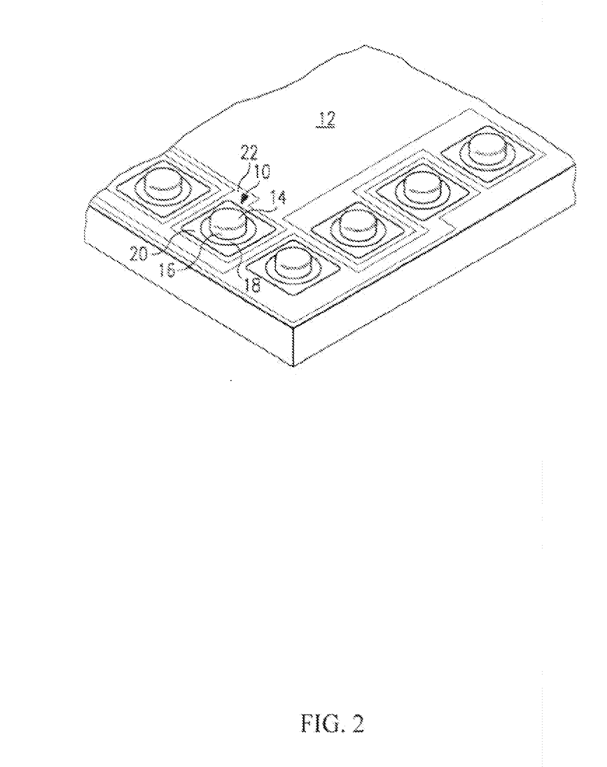

FIG. 2 illustrates an oblique view of a compliant bump 10 formed according to embodiments of the present invention formed on IC chip 12. Compliant bump 10 includes top surface 14 that connects to side portion 16. Side portion 16 is substantially vertical relative to a horizontal IC chip 12 and connects to base 18. Compliant bump 10 may be formed on bond pad of IC chip 12 to provide connection to lead 22.

While various examples have been described above regarding compliant bumps and various integrated circuits, one of ordinary skill in the art will realize that any number of apparatuses and methods can be provided for making and using such compliant bumps and that those apparatuses and methods are encompassed within the scope of the present invention. In addition, those of ordinary skill in the art will appreciate that there are a number of alternative configuration, not specifically mentioned above, for utilizing the compliant bumps. For example, the bumps may be applied to any number of substrates and are not limited to anyone integrated circuit of particular circuit (e.g., amplifier) for that matter.

It will also be understood that certain of the above-described structures, functions and operations of the above-described embodiments are not necessary to practice the present invention and are included in the description simply for completeness of an example embodiment or embodiments. In addition, it will be understood that specific structures, functions and operations set forth in the above-referenced patents and publications can be practiced in conjunction with the present invention, but they are not essential to its practice. It is therefore to be understood that within the scope of the claims, the invention can be practiced otherwise than as specifically described without actually departing from the spirit and scope of the present invention. Finally, all patents, publications and standards referenced herein are hereby incorporated by reference.

1. An integrated circuit (“IC”) comprising a plurality of compliant bumps for physically contacting and electrically interconnecting to electrical connections on another device, wherein the compliant bumps comprise carbon nanotubes (“CNTs”).

2. The IC as recited in claim 1, wherein the CNTs are single-walled.

3. The IC as recited in claim 1, wherein the CNTs are multi-walled.

4. The IC as recited in claim 1, wherein the compliant bumps comprise a composite that comprise CNTs.

5. The IC as recited in claim 1, wherein the IC is a flip chip.

6. The IC as recited in claim 1, wherein the IC comprises a microprocessor.

7. The IC as recited in claim 1, wherein heads of the compliant bumps comprise a metal layer covering the CNTs.

8. The IC as recited in claim 7, wherein the metal layer comprises gold.

9. The IC as recited in claim 7, wherein the metal layer comprises chromium.

10. A module comprising:
a substrate; and
a plurality of CNT-containing interconnect bumps mounted on the substrate electrically connecting to electrical connections in the substrate, the bumps covered with a metal cap.

11. The module as recited in claim 10, wherein the CNTs are single-walled.

12. The module as recited in claim 10, wherein the CNTs are multi-walled.

13. The module as recited in claim 10, wherein the compliant bumps comprise a composite that comprises CNTs.

14. The module as recited in claim 10, wherein the module is a flip chip.

15. The module as recited in claim 10, wherein the module comprises a microprocessor.

16. The module as recited in claim 10, wherein the metal layer comprises gold.

17. The module as recited in claim 10, wherein the metal layer comprises chromium.
